(19) United States
(12) Patent Application Publication
(10) Pub. No.: US 2009/0134965 A1
(43) Pub. Date: May 28, 2009

(54) EFFICIENT METHODOLOGY FOR THE DECOUPLING FOR MULTI-LOOP RF COIL GEOMETRIES FOR MAGNETIC RESONANCE IMAGING

(75) Inventors: Rostislav Lemdiasov, Worcester, MA (US); Reinhold Ludwig, Paxton, MA (US)

Correspondence Address: Leason Ellis LLP, 81 Main Street, Suite 503, White Plains, NY, 10601, US

(73) Assignee: Insight Neuroimaging Systems LLC, Worcester, MA (US)

(21) Appl. No.: 12/248,548

(22) Filed: Oct. 9, 2008

Related U.S. Application Data
(60) Provisional application No. 60/979,362, filed on Oct. 11, 2007.

(51) Int. Cl. H01F 27/28; G01R 33/32

(52) U.S. Cl. 336/220; 324/318

(57) ABSTRACT

A multi-loop RF coil includes a plurality of channels and is formed of a plurality of coil elements. The coil includes a pair of coil elements that at least partially overlap with one another as part of a geometric decoupling scheme between the pair of coil elements.

### CROSS-REFERENCE TO RELATED APPLICATION

The present application claims the benefit of U.S. patent application Ser. No. 60/979,362, filed Oct. 11, 2007, which is hereby incorporated by reference in its entirety.

### TECHNICAL FIELD

The present invention relates to imaging systems and more particularly, relates to coil decoupling schemes between various coil elements to offer improved performance and results.

### BACKGROUND

Specialized RF coils for application-specific imaging modalities are common in the field of magnetic resonance imaging (MRI). In particular, for the magnetic resonance imaging of the female breast in horizontal and vertical clinical MR instruments a number of single and multi-loop RF coil concepts for single channel, quadrature, and phased array configurations have been devised by a number of inventors. Examples of these systems are described in U.S. Pat. No. 7,084,631 (Qu et al., Aug. 1, 2006), U.S. Pat. No. 6,850,065 (Fujita et al., Feb. 1, 2005), U.S. Pat. No. 6,493,572 (Su et al., Dec. 10, 2002), U.S. Pat. No. 6,377,836 (Arakawa et al., Apr. 23, 2002), U.S. Pat. No. 6,163,717 (Su, Dec. 19, 2000), U.S. Pat. No. 6,023,166 (Eydelnan, Feb. 8, 2000), and U.S. Pat. No. 5,699,802 (Duerr, Dec. 23, 1997), each of which is hereby incorporated by reference in its entirety.

Often the individual loops or coil elements are laid out in planar and orthogonal planes with respect to the main magnet in the clinical MR instrument. For example, in FIG. 1, the combination structure of a 7-channel RF coil configuration is illustrated and consists of four planar coils (or loops). Two coils are each placed on two planes that are positioned a certain distance apart. These coils can then be complemented by three additional coils vertically oriented with respect to the original four coils.

In a multi-channel receiver system, the MR signal obtained by a multi-loop breast coil system can be configured such that each loop or coil element is selectively tuned to the resonance frequency of the MR instruments, while the remaining loops, or coil elements, are detuned. As a result, by tuning and detuning individual coil elements, parallel MR imaging is accomplished which enables high resolution imaging of selective regions of interest and concomitantly more rapid image formation.

Unfortunately, when connecting each of the loops, or coil elements, to a receiving channel of the MR instrument, coupling between the tuned and detuned loops can occur. This is due to the fact that the signal received by one loop is also received by neighboring loops, despite detuning measures that involve preamplifier detuning. The coupling is most prominent for the orthogonal loop in the center of the configuration and its adjacently positioned planar loops. There is therefore a perceived need for a coil construction that offers provides improves coil decoupling schemes between various coil elements to offer improved performance and results.

### SUMMARY

A multi-loop RF coil according to one embodiment of the present invention includes a plurality of channels and is formed of a plurality of coil elements. The coil includes a pair of coil elements that overlap with one another as part of a geometric decoupling scheme between the pair of coil elements.

In another embodiment, an RF coil that has a plurality of channels includes a plurality of coil elements and a hybrid decoupling scheme between the coil elements that is a combination of geometric and capacitive decoupling.

In another embodiment, a multi-loop RF coil that has a plurality of channels that includes a plurality of coil elements. A first pair of coils that are disposed in one plane overlap with one another as part of a geometric decoupling scheme between the first pair of coils. In addition, one vertical coil is partially decoupled from the first pair of coils by a bridge over the overlapping portions of the first pair of coils.

### BRIEF DESCRIPTION OF THE DRAWING FIGURES

FIG. 1 is a schematic of a structure of a conventional 7-channel RF breast coil consisting of two loops placed on two separate planes and complemented by three orthogonal loops, wherein the overall dimensions are given in meters;

FIG. 2 is a schematic of a geometrical decoupling scheme between coil elements of a 7-channel coil system according to one exemplary embodiment;

FIG. 3 is a schematic of the 7-channel coil system according to one embodiment showing the deployment of tuning, matching, and decoupling capacitors;

FIGS. 4a-g are schematic illustrations of the 7-channel coil system showing current flow in each of the seven channels; and

FIG. 5 is a schematic illustration of a magnetic field B₁, produced in the left cross-sectional plane by the 7-channel coil configuration of the present invention.

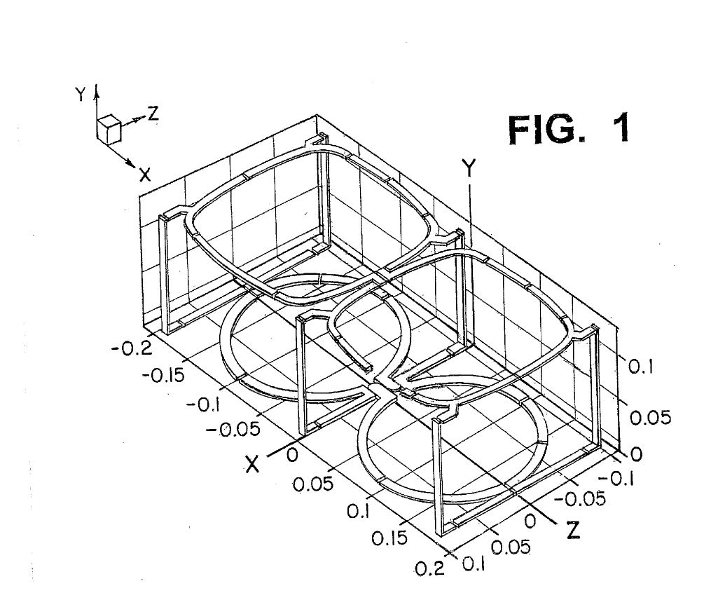

### DETAILED DESCRIPTION OF PREFERRED EMBODIMENTS

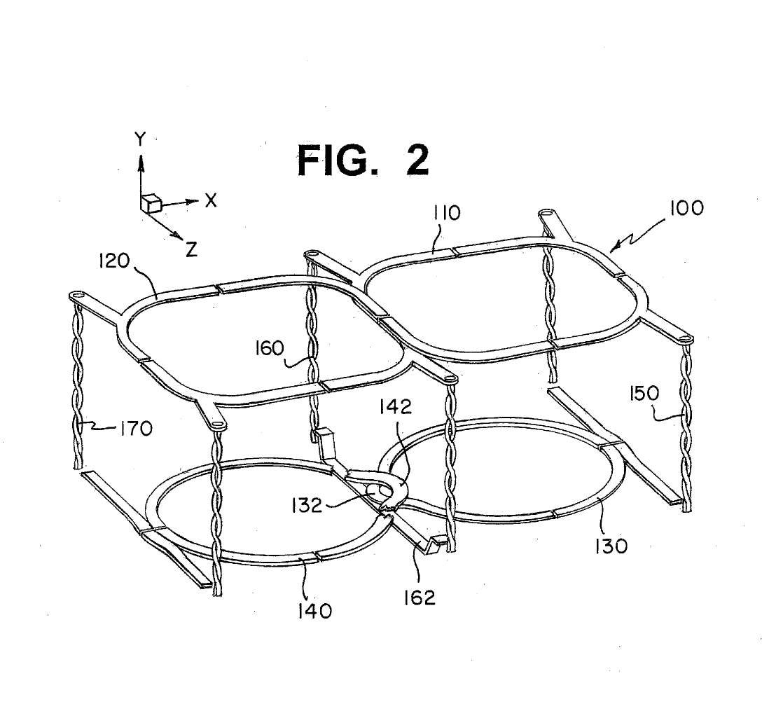

FIG. 2 is a schematic illustrating a 7-channel RF coil 100 according to one exemplary embodiment of the present invention. The 7-channel RF coil 100 is formed of seven coils, namely, a first coil (coil 1) 110; a second coil (coil 2) 120, a third coil (coil 3) 130, a fourth coil (coil 4) 140, a fifth coil (coil 5) 150, a sixth coil (coil 6) 160, and a seventh coil (coil 7) 170. The RF coil 100 is formed of four planar or loop coils positioned on different planes and in particular, coils 110, 120, 130 and 140 are loop coils with coils 110, 120 disposed in one plane and coils 130, 140 disposed in another plane that is spaced from the one plane.

The RF coil 100 has the following loop (or channel) assignments: coil 110 represents the upper right channel, coil 120 represents the upper left channel, coil 130 represents the lower right channel, coil 140 represents the lower left channel, coil 150 represents the vertical right channel, coil 160 represents the vertical middle channel, and coil 170 represents the vertical left channel.

Moreover, each coil element shown in FIG. 2 has a number of breaks which are populated by lumped components, including (a) tuning capacitors (seven), (b) matching capacitors (seven), and (c) decoupling capacitors (seven). The values of these components are chosen to ensure appropriate tuning, matching of each coil, as well as capacitive decoupling of certain coil pairs.

Capacitive decoupling is used between the vertical middle loop 160 and the lower right loop 130 and lower left loop 140. At the same time, the vertical middle loop 160 is only partially decoupled from the upper right loop 110 and upper left loop 120 by a bridge over the two overlapping segments of the lower right loop 130 and lower left loop 140. Partial decoupling is sufficient in this case, because preamplifier decoupling (using low input impedance preamplifier) is additionally used for each loop as seen in FIG. 2. In the coil 100 of the present invention, capacitive decoupling between the middle vertical loop 160 and upper left and right loops 120, 130 is not used. This could create additional current paths, which would be very difficult to control.

FIG. 2 thus illustrates a geometric decoupling strategy between coil elements 130, 140, 160 for the 7-channel RF coil arrangement displayed.

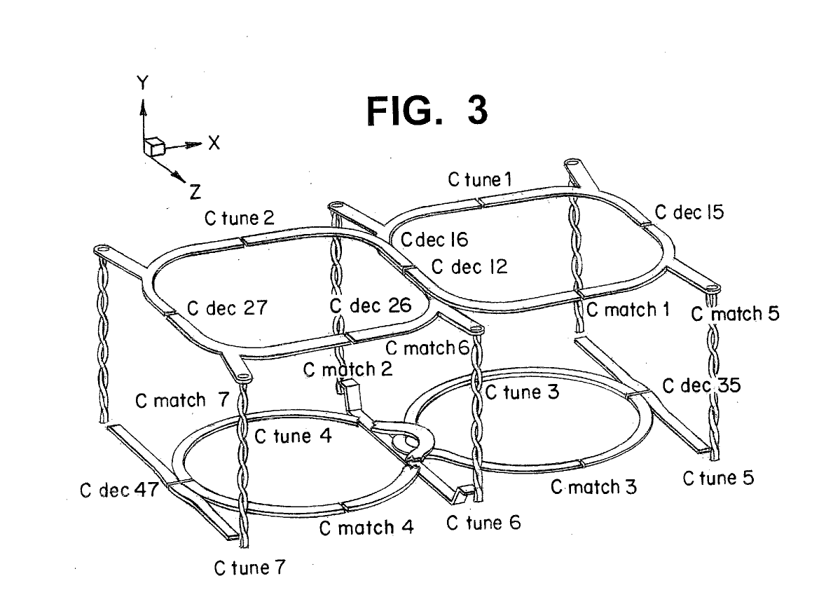

FIG. 3 shows a suitable (exemplary) deployment and labeling of the tuning, matching, and decoupling capacitors for the coil element configuration of FIG. 2.

More particularly, in FIG. 3, for example, “C dec 27” is a decoupling capacitor that decouples coils 2 and 7 (coil 120, coil 170). “C dec 47” (as well as “C dec 35”) denotes four capacitors. The following coil pairs are decoupled by suitable choices of capacitors:

1. Coil 1 (coil 110)-Coil 2 (coil 120)

2. Coil 1 (coil 110)-Coil 6 (coil 160)

3. Coil 2 (coil 120)-Coil 6 (coil 160)

4. Coil 1 (coil 110)-Coil 5 (coil 150)

5. Coil 2 (coil 120)-Coil 7 (coil 170)

6. Coil 3 (coil 130)-Coil 5 (coil 150)

7. Coil 4 (coil 140)-Coil 7 (coil 170)

Tuning capacitors for respective coils are indicated by “C tune x,” where x is the coil number. For example, “C tune 1” refers to a tuning capacitor for coil 1. Similarly, matching capacitors are indicated by “C match x,” where x is the coil number. For example, “C match 1” refers to a matching capacitor for coil 1.

However, unlike previous capacitive decoupling attempts reported in the literature, an inductive decoupling is used for coils 3 and 4 (coils 130, 140) by creating an overlap of the conductive coil structures. As shown in FIG. 2, the coil 140 includes a portion 142 that overlaps a portion 132 of the coil 130 to create the inductive decoupling. As shown in FIG. 2, each of the coils 130, 140 includes an irregular portion that is different from the remaining portion of the coil. The irregular portions of the coils 130, 140 overlap one another and are positioned above the bridge 162. The bridge 162 can be a continuous coil structure that has a number of bends formed therein to allow the overlapping portions of coils 3 and 4 to be disposed thereover. In other words, instead of being a more planar coil like coils 5 and 7, the coil 6 is bent to allow the coil 6 to extend across the overlapping portions of the coil 3 and 4 without obstructing them since this bent portion lies in a different plane that is spaced from the plane(s) that contain the overlapped portions of the coils 3 and 4.

In the illustrated embodiment, the coil 4 lies over coil 3; however, the opposite can be true in that coil 3 can lie over coil 4.

As already mentioned above, Coil 6 (coil 160) features a bridge 162 that is positioned below the plane where Coils 3 and 4 (coils 130, 140) are located. Even though the pairs Coil 3-Coil 6 (coils 130, 160) and Coil 4-Coil 6 (coils 140, 160) are not capacitively decoupled, the bridge 162 helps to decrease the amount of coupling.

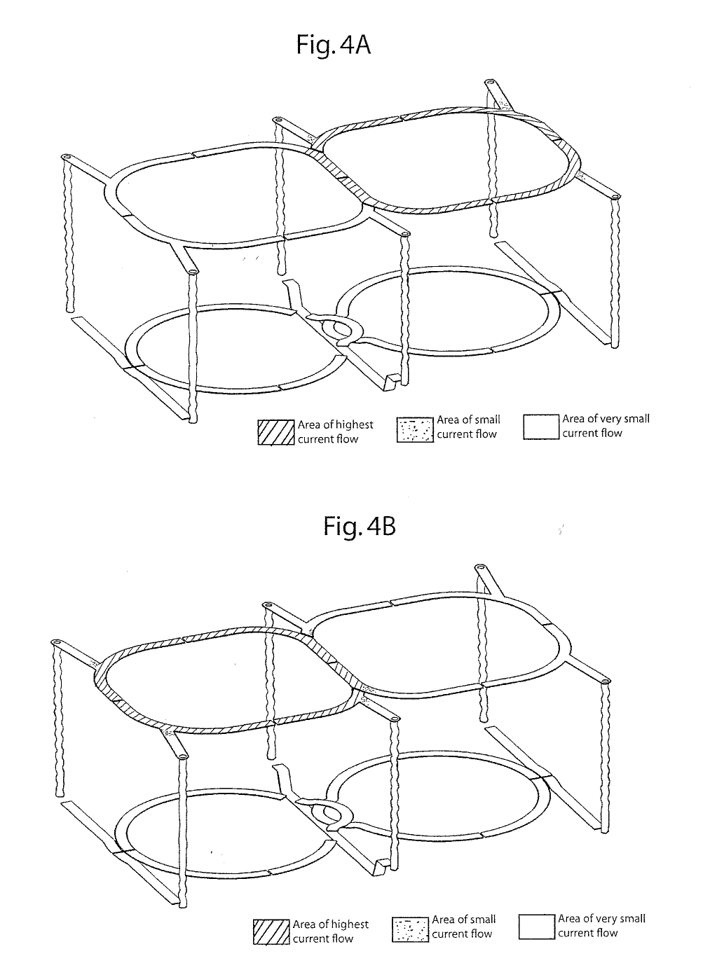

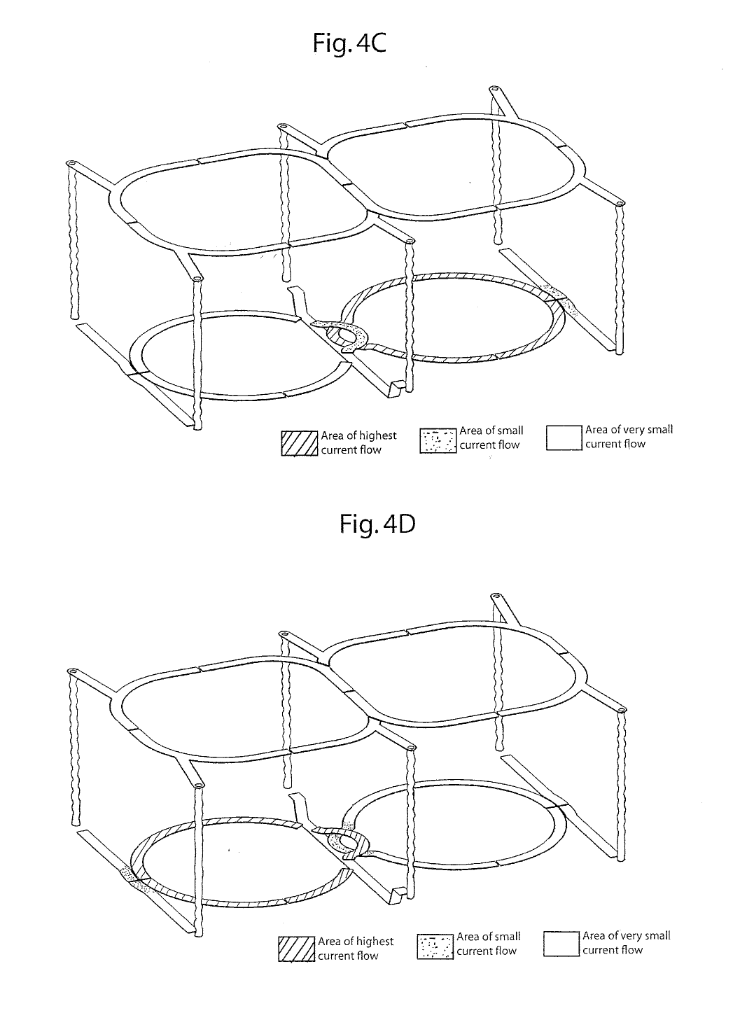

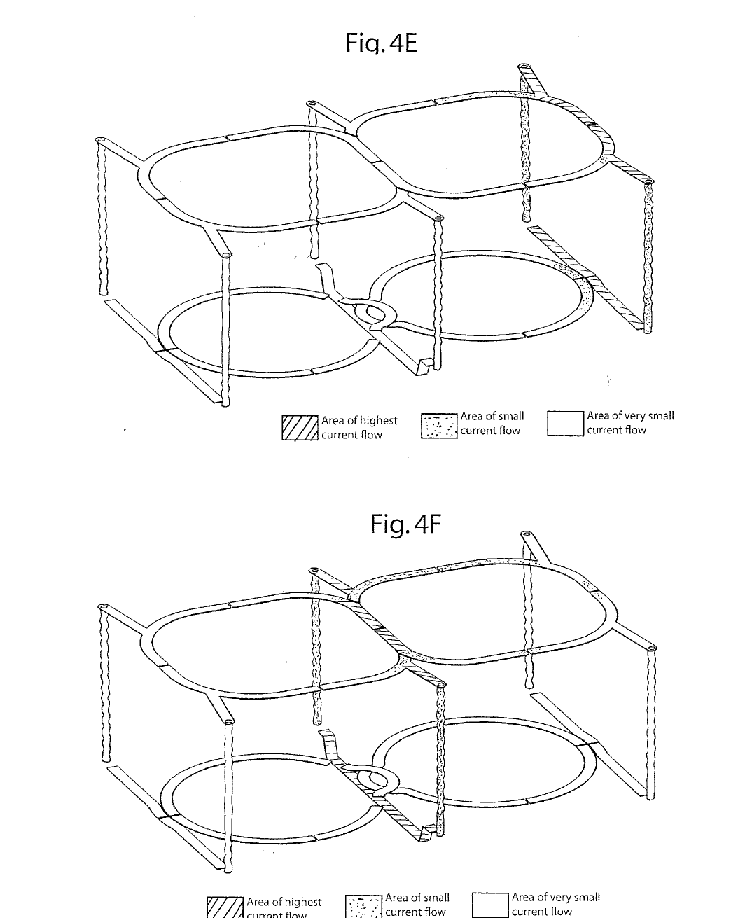

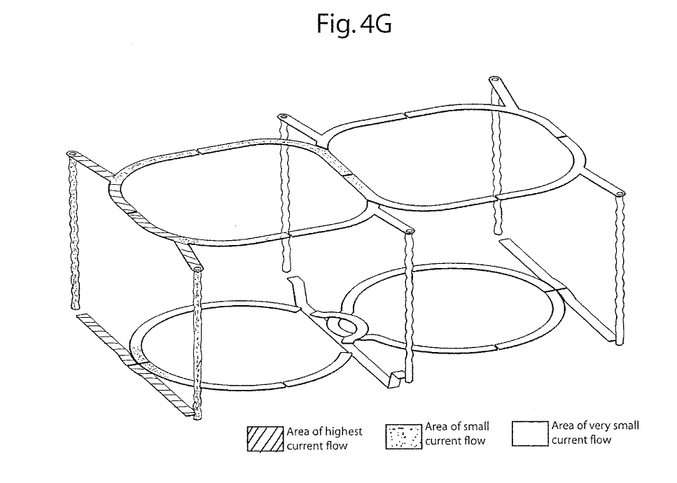

The effectiveness of the disclosed geometric as well as the associated electrical decoupling is demonstrated in FIGS. 4(a)-(g), where the current flow in the seven coil elements (110, 120, 130, 140, 150, 160, 170) is predicted through a Method of Moments numerical modeling program (details of the program are disclosed in the publication Time domain formulation of the method of moments for inhomogeneous conductive bodies at low frequencies, by Lemdiasov, R. A., Obi, A., and Ludwig, R, IEEE Transactions on Antennas and Propagation, v 54, n 2, pt. 2, February 2006, pp. 706-14), which is incorporated by reference in its entirety. In FIG. 4, cross hatching is used to denote the highest current flow, resulting in the respective MR signal acquisition of Coil elements 1 to 7. Additional cross hatching is used to indicate small and very small current flow and a lack of cross hatching denotes no current flow. FIG. 4a thus shows the excitation of coil element 1; FIG. 4b thus shows the excitation of coil element 2; FIG. 4c thus shows the excitation of coil element 3; FIG. 4d thus shows the excitation of coil element 4; FIG. 4e thus shows the excitation of coil element 5; FIG. 4f thus shows the excitation of coil element 6; and FIG. 4g thus shows the excitation of coil element 7.

As can be seen in FIGS. 4a-4g, when individually tuned, each coil element carries its own current. Neighboring coil elements display very little current and therefore indicate good decoupling behavior.

According to reciprocity principle, the sensitivity of a particular coil to the radiation from the biological load is proportional to the magnetic field of the coil, if the latter is driven by an external voltage source. The magnetic B₁ field of these coils can be calculated, provided that the coils take the same amount of input power. The signal-to-noise (SNR) of a coil is proportional to B₁/\sqrt{P}, where P is input power. Finally, the squares of magnetic fields of the seven coils can be added according to the formula:

$$\sqrt{{\sum }_{n = 1}^{7} {B}_{1 n}^{2}} .$$

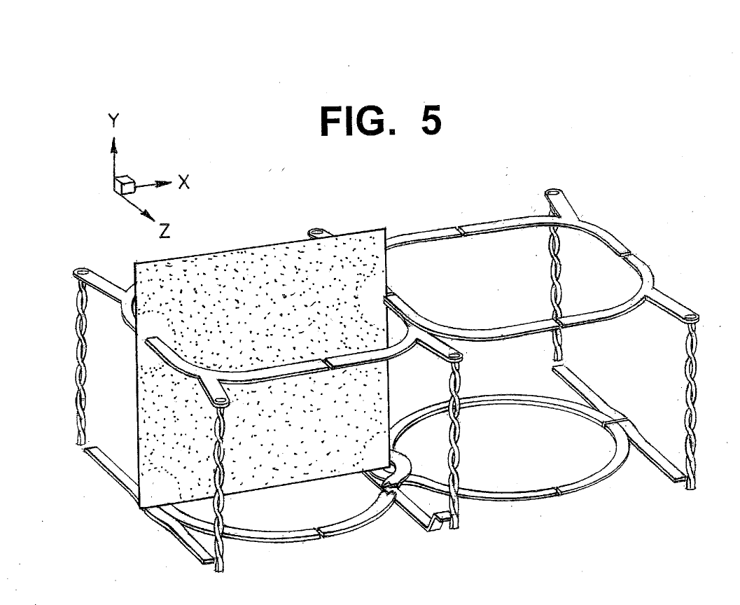

The resulting field is shown in FIG. 5.

What is claimed is:

1. A multi-loop RF coil having a plurality of channels comprising:
a plurality of coil elements, wherein a pair of coil elements overlap with one another as part of a geometric decoupling scheme between the pair of coil elements.

2. The RF coil of claim 1, wherein the plurality of coil elements comprises a plurality of coil elements that are located within two spaced planes, the pair of overlapping coil elements being located within one of the spaced planes.

3. The RF coil of claim 1, wherein the pair of overlapping coil elements produce inductive decoupling between the coil elements.

4. The RF coil of claim 1, wherein there are seven coil elements that correspond with seven channels.

5. The RF coil of claim 1, wherein there are four planar coil elements arranged in two planes spaced apart from one another and three orthogonal coil elements vertically oriented with respect to the four planar coil elements.

6. The RF coil of claim 5, wherein the four planar coil elements comprise an upper left coil element, an upper right coil element, a lower left coil element and a lower right coil element, and the three orthogonal coil elements comprise a vertical left coil element, a vertical middle coil element and a vertical right coil element.

7. The RF coil of claim 6, wherein the lower left coil element and lower right coil element overlap with one another.

8. The RF coil of claim 1, wherein each coil element includes a number of breaks in which one or more components are disposed.

9. The RF coil of claim 8, wherein the one or more components are selected from the group consisting of tuning capacitors, matching capacitors, and decoupling capacitors.

10. The RF coil of claim 1, wherein the pair of coil elements that overlap with one another are located in the same plane and result in inductive decoupling between the pair of coil elements.

11. The RF coil of claim 1, wherein the decoupling scheme includes decoupling between the pair of coil elements and at least one other coil element.

12. The RF coil of claim 7, wherein the vertical middle coil element is partially decoupled from the upper right coil element and upper left coil element by a bridge over the overlapping portions of the lower left coil element and lower right coil element.

13. The RF coil of claim 12, wherein the bridge is positioned below the plane that contains the lower left coil element and lower right coil element.

14. The RF coil of claim 12, wherein each of the lower right coil element and vertical middle coil pair and the lower left coil element and the vertical middle coil pair is not capacitively decoupled.

15. The RF coil of claim 6, wherein the following coil pairs are decoupled by capacitors: (1) upper left coil element and upper right coil element; (2) upper right coil element and vertical middle coil element; (3) upper left coil element and vertical middle coil element; (4) upper right coil element and vertical right coil element; (5) upper left coil element and vertical left coil element; (6) lower right coil element and vertical right coil element; and (7) lower left coil element and vertical left coil element.

16. An RF coil having a plurality of channels comprising:
a plurality of coil elements; and
a hybrid decoupling scheme between the coil elements that is a combination of geometric and capacitive decoupling.

17. A multi-loop RF coil having a plurality of channels comprising:
a plurality of coil elements, wherein a first pair of coil elements that are disposed in one plane overlap with one another as part of a geometric decoupling scheme between the first pair of coil elements, wherein one vertical coil element is partially decoupled from the first pair of coil elements by a continuous bridge that is part of a coil element and extends across the overlapping portions of the first pair of coil elements.

18. The RF coil of claim 17, wherein the bridge is a section of one of the coil elements that is bent to pass below the overlapping first pair of coil elements, the bridge serving to decrease the amount of coupling between the coil elements even though the coil elements of the first pair are not capacitively decoupled.

19. The RF coil of claim 18, wherein there are four planar coil elements arranged in two planes spaced apart from one another and three orthogonal coil elements vertically oriented with respect to the four planar coil elements.

20. The RF coil of claim 19, wherein the four planar coil elements comprise an upper left coil element, an upper right coil element, a lower left coil element and a lower right coil element, and the three orthogonal coil elements comprise a vertical left coil element, a vertical middle coil element and a vertical right coil element.

21. The RF coil of claim 20, wherein the lower left coil element and lower right coil element overlap with one another.

22. The RF coil of claim 17, wherein each coil element includes a number of breaks in which one or more components are disposed.

23. The RE coil of claim 22, wherein the one or more components are selected from the group consisting of tuning capacitors, matching capacitors, and decoupling capacitors.
